(19) United States
(12) Patent Application Publication
(10) Pub. No.: US 2024/0069116 A1
(43) Pub. Date: Feb. 29, 2024

(54) METHOD, SYSTEM, ELECTRONIC DEVICE AND STORAGE MEDIUM FOR DETERMINING PERFORMANCE OF POWER BATTERY

(71) Applicant: SHANGHAI MAKESENS ENERGY STORAGE TECHNOLOGY CO., LTD., Shanghai (CN)

(72) Inventors: Peng Ding, Shanghai (CN); Yanwen Zhang, Shanghai (CN); Weikun Wu, Shanghai (CN); Haowen Ren, Shanghai (CN); Zonglin Cai, Shanghai (CN); Xiaohua Chen, Shanghai (CN); Xiao Yan, Shanghai (CN); Enhai Zhao, Shanghai (CN); Pei Song, Shanghai (CN); Danfei Gu, Shanghai (CN); Pingchao Hao, Shanghai (CN)

(21) Appl. No.: 18/237,483

(22) Filed: Aug. 24, 2023

(30) Foreign Application Priority Data
Aug. 25, 2022 (CN) 202211023473.4

(51) Int. Cl. G01R 31/389; G01R 31/371; H02J 7/00

(52) U.S. Cl. CPC G01R 31/389; G01R 31/371; H02J 7/0047

(57) ABSTRACT

The invention discloses a method, a system, an electronic device, and a storage medium for determining performance of a power battery. The method includes the following steps: acquiring historical data of the power battery in at least two charging processes; determining, according to historical data in one charging process, a dQ/dV curve and a direct current internal resistance corresponding to said charging process; calculating a relative change rate of internal resistance capacity in any two charging processes; and determining the performance of the power battery according to the relative change rate of internal resistance capacity and a relative change rate of internal resistance capacity range corresponding to fault type. The invention can effectively determine whether the performance of the power battery is abnormal by combining, in the two charging processes, the target peak value of a dQ/dV curve of the power battery and the change in direct current internal resistance.

### CROSS-REFERENCE TO RELATED PATENT APPLICATION

This application claims priority to and the benefit of Chinese Patent Application No. 202211023473.4, filed Aug. 25, 2022, which is incorporated herein in its entirety by reference.

### FIELD OF THE INVENTION

The invention relates generally to the field of safety diagnosis of power batteries, in particular to a method, a system, an electronic device, and a storage medium for determining performance of a power battery.

### BACKGROUND OF THE INVENTION

Lithium battery accidents are the result of a combination of thermodynamic and electrochemical processes: when the rate at which a lithium battery releases heat exceeds the rate of heat dissipation, the temperature of the lithium battery will increase as heat accumulates; elevated temperatures can enhance the chemical activity of the internal materials in the lithium battery, accelerating chemical reaction rates or introducing new side reactions, leading to the continued release of more heat and forming a vicious cycle. Prolonged temperature increase can cause the internal materials of the lithium battery to melt or decompose, and in severe cases, it can lead to serious faults such as internal short circuits, thermal runaway, and the like.

Most internal failures of lithium batteries are a result of improper usage during operation, and the likelihood of lithium battery accidents is greatly increased by various forms of misuse. Among these, improper charging processes, such as overcharging, high temperatures, low temperatures, and high rates, frequently lead to incidents of electric vehicle fires.

Currently, research on overcharging failures in lithium batteries mainly involves misuse experiments with higher rates and deeper overcharge levels. Such experiments can cause mass lithium plating and temperature rise in a test battery within a short period of time, leading to internal short circuits and thermal runaway faults. This approach is favorable for evaluating battery safety characteristics but does not provide a clear view of the external characteristic changes of the whole process from fault occurrence to failure development. However, in actual cases, lower rates and shallower overcharge levels may not lead to sudden failures due to phenomena like lithium plating, but will still cause events such as electrolyte solvent co-intercalation, binder decomposition, and the like, resulting in exfoliation of the negative electrode graphite. With continued cycling and the ongoing loss of active material in the negative electrode, the phenomenon of negative electrode lithium deposition is exacerbated, leading to the loss of active lithium material in the negative electrode and a risk of short-term failure. Therefore, existing experiments with higher rates and deeper overcharge levels are inadequate for assessing the safety characteristics of lithium batteries in actual cases.

Therefore, a heretofore unaddressed need exists in the art to address the aforementioned deficiencies and inadequacies.

### SUMMARY OF THE INVENTION

The technical problem to be solved by the present invention is to overcome the shortcomings in the prior art of being unable to evaluate the safety characteristics of lithium batteries under actual conditions, and the invention provides a method, a system, an electronic device, and a storage medium for determining the performance of a power battery.

The invention solves the above technical problem through the following technical scheme:

The first aspect of the present invention provides a method for determining the performance of a power battery, including the following steps:
acquiring historical data of a power battery in at least two charging processes;
determining, according to historical data in one charging process, a dQ/dV curve and a direct current internal resistance corresponding to said charging process;
calculating a relative change rate of internal resistance capacity in any two charging processes; wherein the relative change rate of internal resistance capacity is determined according to a difference between a first direct current internal resistance and a second direct current internal resistance and a difference between a target peak value of a first dQ/dV curve and a target peak value of a second dQ/dV curve, the first direct current internal resistance and the first dQ/dV curve corresponding to one charging process, the second direct current internal resistance and the second dQ/dV curve corresponding to the other charging process, and two peaks corresponding to the two target peak values being used for representing the same electrochemical reaction;
and determining the performance of the power battery according to the relative change rate of internal resistance capacity and a relative change rate of internal resistance capacity range corresponding to fault type.

Optionally, the step of determining the performance of the power battery according to the relative change rate of internal resistance capacity and the relative change rate of internal resistance capacity range corresponding to fault type comprises:
judging whether the relative change rate of the internal resistance capacity falls within the relative change rate of internal resistance capacity range corresponding to fault type;
if yes, determining that the performance of the power battery is abnormal, and/or determining that the power battery has a fault corresponding to the fault type;
and if no, determining that the performance of the power battery is normal.

Optionally, the method further includes the following steps:
if the relative change rate of internal resistance capacity falls within the relative change rate of internal resistance capacity range corresponding to fault type, outputting a warning message;
wherein the warning message is configured to represent a performance abnormity of the power battery and/or existence of the fault of the power battery corresponding to fault type.

Optionally, the step of calculating the relative change rate of the internal resistance capacity in any two charging processes comprises:
determining the target peak value of the first dQ/dV curve and the target peak value of the second dQ/dV curve according to initial charge levels in the two charging processes.

A second aspect of the present invention provides a system for determining performance of a power battery, comprising:
a data acquisition module configured to acquire historical data of the power battery in at least two charging processes;
a first determination module configured to determine, according to historical data in one charging process, a dQ/dV curve and a direct current internal resistance corresponding to said charging process;
a change rate calculation module configured to calculate a relative change rate of internal resistance capacity in any two charging processes; wherein the relative change rate of internal resistance capacity is determined according to a difference between a first direct current internal resistance and a second direct current internal resistance and a difference between a target peak value of a first dQ/dV curve and a target peak value of a second dQ/dV curve, the first direct current internal resistance and the first dQ/dV curve corresponding to one charging process, the second direct current internal resistance and the second dQ/dV curve corresponding to the other charging process, and two peaks corresponding to the two target peak values being configured to represent the same electrochemical reaction;
and a second determination module configured to determine the performance of the power battery according to the relative change rate of internal resistance capacity and the relative change rate of internal resistance capacity range corresponding to fault type.

Optionally, the second determination module is configured to determine whether the relative change rate of internal resistance capacity falls within the relative change rate of the internal resistance capacity range corresponding to fault type, and if yes, determine that the performance of the power battery is abnormal, and/or determine that the power battery has a fault corresponding to the fault type; and if no, determine that the performance of the power battery is normal.

Optionally, the system further includes a message notification module configured to output a warning message if the relative change rate of internal resistance capacity falls within the relative change rate of internal resistance capacity range corresponding to fault type;
wherein the warning message is configured to represent a performance abnormity of the power battery and/or existence of the fault of the power battery corresponding to the fault type.

Optionally, the change rate calculation module is further configured to determine the target peak value of the first dQ/dV curve and the target peak value of the second dQ/dV curve based on initial charge levels in the two charging processes.

A third aspect of the present invention provides an electronic device comprising a memory, a processor, and a computer program stored on the memory and executable on the processor, wherein the processor implements the method for determining the performance of a power battery according to the first aspect when executing the computer program.

A fourth aspect of the present invention provides a computer-readable storage medium on which a computer program is stored, which, when executed by a processor, implements the method for determining the performance of a power battery according to the first aspect.

Based on common knowledge in the field, the above optional conditions can be combined arbitrarily to obtain the preferred embodiments of the invention.

The positive progress effects of the invention are as follows: determining, according to historical data of the power battery in at least two charging processes, the dQ/dV curve and the direct current internal resistance corresponding to said charging processes, calculating the relative change rate of internal resistance capacity of the power battery according to the target peak value of the dQ/dV curve and the direct current internal resistance corresponding to any two charging processes, and determining the performance of the power battery according to whether the relative change rate of internal resistance capacity falls within the relative change rate of internal resistance capacity range corresponding to fault type. To effectively determine whether the performance of the power battery is abnormal, in the two charging processes, the target peak value of the dQ/dV curve of the power battery and the change in the direct current internal resistance are combined.

### BRIEF DESCRIPTION OF THE DRAWINGS

The accompanying drawings illustrate one or more embodiments of the invention and, together with the written description, serve to explain the principles of the invention. The same reference numbers may be used throughout the drawings to refer to the same or like elements in the embodiments.

FIG. 1 is a schematic diagram of an incremental capacity curve of normal aging of a power battery according to embodiments of the present invention.

FIG. 2 is a schematic diagram of an incremental capacity curve of overcharge aging of a power battery according to embodiments of the present invention.

FIG. 3 is a flowchart of a method for determining performance of a power battery according to Embodiment 1 of the present invention.

FIG. 4 is a flowchart of another method for determining performance of a power battery according to Embodiment 1 of the present invention.

FIG. 5 is a schematic structural diagram of a system for determining performance of a power battery according to Embodiment 1 of the present invention.

FIG. 6 is a schematic structural diagram of an electronic device according to Embodiment 2 of the present invention.

### DETAILED DESCRIPTION OF THE INVENTION

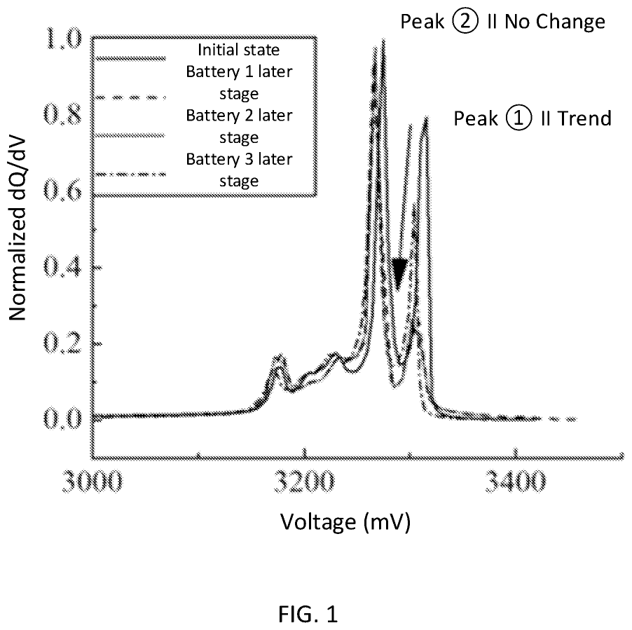

Embodiments of the invention are described below through specific examples in conjunction with the accompanying drawings in FIGS. 1-6, and those skilled in the art can easily understand other advantages and effects of the invention from the content disclosed in this specification. The invention can also be implemented or applied through other different specific implementations, and various modifications or changes can be made to the details in this specification according to different viewpoints and applications without departing from the spirit of the invention. It should be noted that, in the case of no conflict, the following embodiments and features in the embodiments can be combined with each other.

It should be noted that the drawings provided in the following embodiments are merely illustrative in nature and serve to explain the principles of the invention, and are in no way intended to limit the invention, its application, or uses. Only the components related to the invention are shown in the drawings rather than the number, shape and size of the components in actual implementations. For components with the same structure or function in some figures, only one of them is schematically shown, or only one of them is marked. They do not represent the actual structure of the product. Dimensional drawing, the type, quantity and proportion of each component can be changed arbitrarily in its actual implementations. More complicated component layouts may also become apparent in view of the drawings, the specification, and the following claims.

The terminology used herein is for the purpose of describing particular embodiments only and is not intended to be limiting of the invention. As used herein, “a” not only means “only one,” but also means “more than one.” The term “and/or” used in the description of the present application and the appended claims refers to any combination and all possible combinations of one or more of the associated listed items, and includes these combinations. The terms “first,” “second,” etc. are only used for distinguishing descriptions, and should not be construed as indicating or implying relative importance.

It should be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

In order to more clearly illustrate the embodiments of the invention or the technical solutions in the prior art, the following description will explain the specific embodiments of the invention with reference to the accompanying drawings. It is evident that the drawings in the following description are only examples of the invention, from which other drawings and other embodiments can be obtained by a person skilled in the art without inventive effort.

The invention is further illustrated by the following examples, which are not intended to limit the scope of the invention.

The power battery has different performances under different aging mechanisms, and taking a lithium battery as an example, the main performances include loss of active material of the delithiated negative electrode (LAMdene), loss of lithium inventory (LLI), loss of active material of the lithiated negative electrode (LAMline), increase of direct current internal resistance, and the like.

Research shows that under different aging mechanisms, each peak of a dQ/dV curve has different changes, some peaks are reduced, some peaks are increased, and other peaks are translated. The dQ/dV curve may be referred to as an incremental capacity curve or a differential capacity curve, and is configured to calculate a change in battery capacity in a constant voltage interval, and a ratio of a measured two capacity differences before and after the change to a corresponding voltage difference.

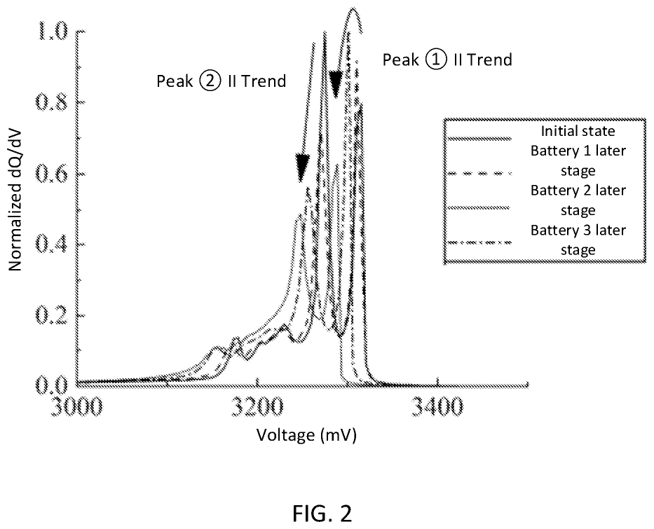

FIG. 1 is used for showing the incremental capacity curve of normal aging of the power battery, and FIG. 2 is used for showing the incremental capacity curve of overcharge aging of the power battery. As shown in FIGS. 1 and 2, overcharge aging causes peak \textcircled{1} II of the dQ/dV curve to rise and peak \textcircled{2} II to fall.

Based on the above, the embodiment combines the target peak value of the dQ/dV curve of the power battery during two charging processes and the change in the direct current internal resistance to determine whether the performance of the power battery is abnormal.

### Embodiment 1

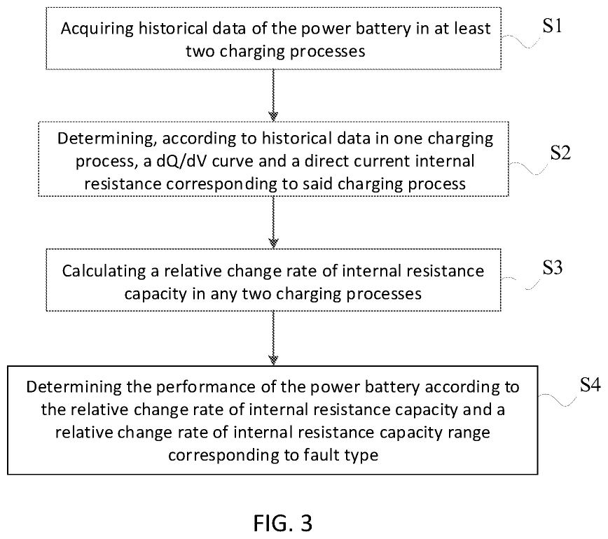

FIG. 3 is a schematic flowchart of a method for determining performance of a power battery according to the present embodiment, where said method for determining performance of a power battery may be executed by a system for determining performance of a power battery, said system for determining performance of a power battery may be implemented by software and/or hardware, and said system for determining performance of a power battery may be part or all of an electronic device. The electronic device in the present embodiment may be a personal computer (PC), such as a desktop, an all-in-one machine, a notebook computer, a tablet computer, and the like, and may also be a terminal device such as a mobile phone, a wearable device, and a personal digital assistant (PDA). The following describes the method for determining the performance of the power battery provided in the present embodiment with an electronic device as an execution subject.

As shown in FIG. 3, the method for determining the performance of the power battery provided by the present embodiment may include the following steps S1 to S4:

At step S1, historical data of the power battery in at least two charging processes are acquired.

The power battery is a power supply for providing a power source for the tool, and is a storage battery for providing power for electric vehicles, electric trains, electric bicycles and the like, and specifically can be a lithium battery, a nickel-metal hydride battery and the like.

In specific implementations, the historical data during charging may include the voltage of the power battery Uₖ, current I, time Tₖ and so on. Uₖ is the voltage sampled at the kth time, and Tₖ is the time sampled at the kth time.

At step S2, according to historical data in a charging process, a dQ/dV curve and a direct current internal resistance corresponding to said charging process are determined.

Specifically, the following formula can be used to calculate the dQ/dV value from which several dQ/dV values can be derived:

$$\frac{dQ}{d V} = \frac{I * Δ t}{3600 * ΔV} ;$$

wherein Δt=Tₖ₊₁−Tₖ, characterizing the time interval between two consecutive samples, and ΔV=Uₖ₊₁−Uₖ, characterizing the voltage difference between two consecutive samples.

In specific implementations, the direct current internal resistance can be extracted by adopting a charging pulse mode. Specifically, in each historical charging process of the power battery, when the electric quantity reaches Q1, the power battery is first set to rest for a period of time, then is charged for a period of time by using pulse current, and then is set to rest for a period of time. Q1 may be set according to actual conditions, for example, being set to 90%, 95%, etc. In order to improve the accuracy of extracting the direct current internal resistance, the resting time period may be set according to the duration of the electrochemical polarization, and may be set to be, for example, 5 minutes or 10 minutes. The charging time period can also be set according to actual conditions, for example, setting the charging time period to 10 seconds. The value of the pulse current can be determined according to the maximum allowable current of the power battery Iₘₐₓ, for example, setting to 75% Iₘₐₓ.

Specifically, the following formula can be used to calculate the direct current internal resistance of the power battery in the nth charging process Rₙ:

$${R}_{n} = \frac{Δ U}{0.75 * {I}_{max}} ;$$

Wherein ΔU is the voltage rise at the instant of pulse in the nth charging process, that is, the voltage difference after charging with pulse current compared with before charging with pulse current.

At step S3, the relative change rate of internal resistance capacity in any two charging processes is calculated.

The relative change rate of internal resistance capacity is determined according to the difference between the first direct current internal resistance and the second direct current internal resistance and the difference between the target peak value of the first dQ/dV curve and the target peak value of the second dQ/dV curve, the first direct current internal resistance and the first dQ/dV curve corresponding to one charging process, the second direct current internal resistance and the second dQ/dV curve corresponding to the other charging process, and two peaks corresponding to the two target peak values being used for representing the same electrochemical reaction.

In specific implementations, the relative change rate of internal resistance capacity may be a ratio of a difference between the first direct current internal resistance and the second direct current internal resistance to a difference between a target peak value of the first dQ/dV curve and a target peak value of the second dQ/dV curve, and may also be a ratio of a difference between a target peak value of the first dQ/dV curve and a target peak value of the second dQ/dV curve to a difference between the first direct current internal resistance and the second direct current internal resistance.

The dQ/dV curve may have multiple peaks, each peak representing an electrochemical reaction. If the initial charge levels of the power battery during charging are different, the number of peaks in the dQ/dV curve may be different. In an alternative embodiment of step S3, the target peak of the first dQ/dV curve and the target peak of the second dQ/dV curve are determined according to the initial charge levels in the two charging processes.

In specific implementations, if the initial charge level in the two charging processes is less than the preset charge level, a corresponding peak is determined according to the preset charge level, and the peak value of the peak is taken as a target peak value. For example, if the initial charge levels in the two charging processes are less than 30%, the third peak of the first dQ/dV curve is taken as the target peak of the first dQ/dV curve, and the third peak of the second dQ/dV curve is taken as the target peak of the second dQ/dV curve.

In a specific example, the third peak value of the dQ/dV curve corresponding to the nth charging process of the power battery is Mₙ, and the direct current internal resistance is Rₙ, the third peak value of the dQ/dV curve corresponding to the mth charging process is Mₘ, and the direct current internal resistance is Rₘ, and the relative change rate of internal resistance capacity of the power battery Kₘₙ is calculated according to the following formula:

$${K}_{mn} = \frac{{R}_{m} - {R}_{n}}{{M}_{m} - {M}_{n}}$$

At step S4, the performance of the power battery is determined according to the relative change rate of internal resistance capacity and the relative change rate of internal resistance capacity range corresponding to fault type.

Different fault types correspond to different relative change rate of internal resistance capacity ranges. In specific implementations, the fault types may include overcharge, high temperature, low temperature, high rate, and the like.

A lithium battery pack which is the same as the power battery in type and the rated capacity of the power battery can be selected to perform comparison experiments, wherein the comparison experiments comprise single-variable experiments such as overcharge aging, high-temperature aging, low-temperature aging, high-rate aging, and the like. Each single-variable experiment corresponds to one fault type, historical data of the lithium battery pack in the charging process is obtained for each single-variable experiment, the steps S2 and S3 are executed, a plurality of relative change rates of internal resistance capacity are obtained through calculation, and the relative change rate of internal resistance capacity range is obtained according to the maximum value and the minimum value of the relative change rates of internal resistance capacity.

It should be noted that battery information of the power battery, such as battery type BatteryType, rated capacity Cᵣₐₜₑ, maximum single voltage Vₘₐₓ, maximum allowable current Iₘₐₓ, recommended current I_{c}, and the like may be obtained through GBT 27930 “Communication Protocol between Off-Board Conductive Charger and Battery Management System of Electric Vehicles.”

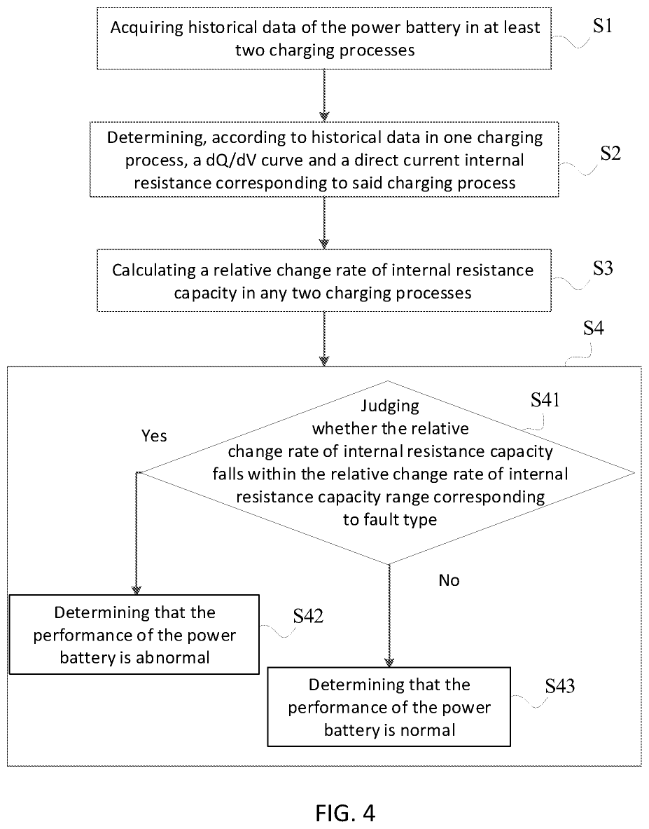

In an alternative embodiment, as shown in FIG. 4, step S4 includes the following steps S41 to S43:

At step S41, the relative change rate of internal resistance capacity is judged as to whether it falls into the internal resistance capacity relative change rate range corresponding to the fault type, executing S42 if yes, and executing S43 if no.

If the relative change rate of internal resistance capacity is less than or equal to the maximum value of the relative change rate of internal resistance capacity range corresponding to fault type and is greater than or equal to the minimum value of the relative change rate of internal resistance capacity range corresponding to fault type, the relative change rate of internal resistance capacity is determined to fall within the relative change rate of internal resistance capacity range corresponding to fault type. If the internal resistance capacity relative change rate is larger than the maximum value of the relative change rate of internal resistance capacity range corresponding to fault type or smaller than the minimum value of the relative change rate of internal resistance capacity range corresponding to fault type, the relative change rate of internal resistance capacity is determined to not fall within the relative change rate of internal resistance capacity range corresponding to fault type.

In specific implementations of step S41, it is determined, for each fault type, whether the relative change rate of internal resistance capacity falls within the relative change rate of internal resistance capacity range corresponding to fault type. If the relative change rate of internal resistance capacity falls within the relative change rate of internal resistance capacity range corresponding to any fault type, step S42 is executed, and if the relative change rate of internal resistance capacity does not fall within the relative change rate of internal resistance capacity ranges corresponding to all fault types, step S43 is executed.

At step S42, the performance of the power battery is determined to be abnormal.

In specific implementations of step S42, it may be further determined that the power battery has a fault corresponding to the fault type. For example, it may be determined that the working conditions of overcharge, high temperature, and the like exist for the power battery.

In specific implementations of step S42, a warning message may be further output. The warning message is configured to represent the performance abnormity of the power battery and/or the fault corresponding to the fault type of the power battery, and the purpose of early warning a user is achieved. The warning message can be sound, light, vibration, voice, and the like.

At step S43, the performance of the power battery is determined to be normal.

In a specific example, the relative change rate of internal resistance capacity range corresponding to high temperature is as follows: 1.13 to 5.29, and the relative change rate of internal resistance capacity range corresponding to overcharge is as follows: 6.05 to 43.37. If the calculated relative change rate of internal resistance capacity of the power battery is 3.52, the power battery is determined to have a high-temperature fault.

In the present embodiment, according to historical data of the power battery in at least two charging processes, a dQ/dV curve and a direct current internal resistance corresponding to the charging processes are determined, the relative change rate of internal resistance capacity of the power battery is calculated according to a target peak value of the dQ/dV curve and the direct current internal resistance corresponding to any two charging processes, and then the performance of the power battery is determined according to whether the relative change rate of internal resistance capacity falls within a relative change rate of internal resistance capacity range corresponding to fault type. Whether the performance of the power battery is abnormal or not can be effectively determined by combining the target peak value of the dQ/dV curve of the power battery in the two charging processes and the change in the direct current internal resistance.

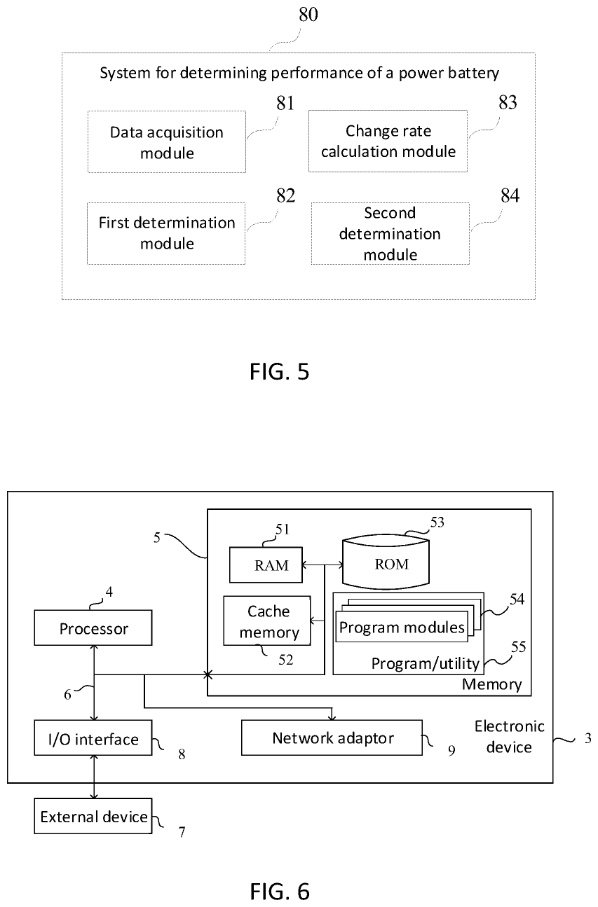

As shown in FIG. 5, the present embodiment further provides a system 80 for determining performance of a power battery, which includes a data acquisition module 81, a first determination module 82, a change rate calculation module 83, and a second determination module 84.

The data acquisition module is configured to acquire historical data of the power battery in at least two charging processes. The first determination module is configured to determine, according to historical data in one charging process, a dQ/dV curve and a direct current internal resistance corresponding to said charging process. The change rate calculation module is configured to calculate the relative change rate of the internal resistance capacity in any two charging processes. The relative change rate of internal resistance capacity is determined according to the difference between the first direct current internal resistance and the second direct current internal resistance and the difference between the target peak value of the first dQ/dV curve and the target peak value of the second dQ/dV curve, the first direct current internal resistance and the first dQ/dV curve corresponding to one charging process, the second direct current internal resistance and the second dQ/dV curve corresponding to the other charging process, and two peaks corresponding to the two target peak values being used for representing the same electrochemical reaction. The second determination module is configured to determine the performance of the power battery according to the relative change rate of internal resistance capacity and the relative change rate of internal resistance capacity range corresponding to fault type.

In an optional implementation, the second determination module is configured to determine whether the relative change rate of internal resistance capacity falls within a relative change rate of internal resistance capacity range corresponding to fault type, and if yes, determine that the performance of the power battery is abnormal, and/or determine that the power battery has a fault corresponding to the fault type; and if no, determine that the performance of the power battery is normal.

In an optional implementation, the performance determination apparatus further includes a message notification module configured to output a warning message if the relative change rate of internal resistance capacity falls within the relative change rate of internal resistance capacity range corresponding to fault type. The warning message is configured to represent the performance abnormity of the power battery and/or the existence of the fault of the power battery corresponding to the fault type.

In an optional implementation, the change rate calculation module is further configured to determine a target peak value of a first dQ/dV curve and a target peak value of a second dQ/dV curve based on initial charge levels during the two charging processes.

It should be noted that the system for determining performance of the power battery in this embodiment may be a separate chip, a chip module, or an electronic device, or may be a chip or a chip module integrated in an electronic device.

Each module/unit included in the system for determining performance of the power battery described in the present embodiment may be a software module/unit, or may also be a hardware module/unit, or may also be a part of a software module/unit, and a part of a hardware module/unit.

### EXAMPLE 2

FIG. 6 is a schematic structural diagram of an electronic device provided in the present embodiment. The electronic device includes at least one processor and a memory communicatively coupled to the at least one processor. The memory stores a computer program executable by the at least one processor, the computer program being executable by the at least one processor to enable the at least one processor to perform the method for determining performance of a power battery of Embodiment 1. The electronic device provided by this embodiment may be a personal computer, such as a desktop, an all-in-one machine, a notebook computer, a tablet computer, and the like, and may also be a mobile phone, a wearable device, a palmtop computer, and other terminal devices. The electronic device 3 shown in FIG. 6 is only an example, and should not bring any limitation to the functions and the scope of use of the embodiments of the present invention.

The components of the electronic device 3 may include, but are not limited to: the at least one processor 4, the at least one memory 5, and a bus 6 connecting the various system components (including the memory 5 and the processor 4).

The bus 6 includes a data bus, an address bus, and a control bus.

The memory 5 may include volatile memory, such as Random Access Memory (RAM) 51 and/or cache memory 52, and may further include Read Only Memory (ROM) 53.

The memory 5 may also include a program/utility 55 having a set (at least one) of program modules 54, such program modules 54 including, but not limited to: an operating system, one or more application programs, other program modules, and program data, each of which, or some combination thereof, may comprise an implementation of a network environment.

The processor 4 executes various functional applications and data processing, such as the method for determining performance of a power battery of Embodiment 1 described above, by running the computer program stored in the memory 5.

The electronic device 3 may also communicate with one or more external devices 7, such as a keyboard, pointing device, etc. Such communication may be via an input/output (I/O) interface 8. Also, the electronic device 3 may communicate with one or more networks (e.g., a Local Area Network (LAN), a Wide Area Network (WAN), and/or a public network such as the Internet) via the network adapter 9. As shown in FIG. 6, the network adapter 9 communicates with other modules of the electronic device 3 via the bus 6. It should be understood that although not shown in FIG. 6, other hardware and/or software modules may be used in conjunction with the electronic device 3, including but not limited to: microcode, device drivers, redundant processors, external disk drive arrays, RAID (disk array) systems, tape drives, and data backup storage systems, to name a few.

It should be noted that although in the above detailed description several units/modules or sub-units/modules of the electronic device are mentioned, such a division is merely exemplary and not mandatory. Indeed, the features and functionality of two or more of the units/modules described above may be embodied in one unit/module according to embodiments of the invention. Conversely, the features and functions of one unit/module described above may be further divided into embodiments by a plurality of units/modules.

### Embodiment 3

The present embodiment provides a computer-readable storage medium on which a computer program is stored, which, when executed by a processor, implements the method for determining performance of a power battery of Embodiment 1.

More specific examples, among others, that the readable storage medium may employ may include, but are not limited to: a portable disk, a hard disk, random access memory, read only memory, erasable programmable read only memory, optical storage device, magnetic storage device, or any suitable combination of the foregoing.

In a possible implementation, the invention may also be implemented in the form of a program product comprising program code for causing an electronic device to carry out the method for determining performance of a power battery in implementing Embodiment 1, when said program product is run on said electronic device.

Program code for carrying out the invention may be written in any combination of one or more programming languages, and the program code may be executed entirely on the electronic device, partly on the electronic device, as a stand-alone software package, partly on the electronic device and partly on a remote device, or entirely on the remote device.

The foregoing description of the exemplary embodiments of the invention has been presented only for the purposes of illustration and description and is not intended to be exhaustive or to limit the invention to the precise forms disclosed. Many modifications and variations are possible in light of the above teaching. The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the invention pertains without departing from its spirit and scope. Accordingly, the scope of the invention is defined by the appended claims rather than the foregoing description and the exemplary embodiments described therein.

What is claimed is:

1. A method for determining performance of a power battery, comprising the following steps:
acquiring historical data of the power battery in at least two charging processes;
determining, according to historical data in one charging process, a dQ/dV curve and a direct current internal resistance corresponding to said charging process;
calculating a relative change rate of internal resistance capacity in any two charging processes; wherein the relative change rate of internal resistance capacity is determined according to a difference between a first direct current internal resistance and a second direct current internal resistance and a difference between a target peak value of a first dQ/dV curve and a target peak value of a second dQ/dV curve, the first direct current internal resistance and the first dQ/dV curve corresponding to one charging process, the second direct current internal resistance and the second dQ/dV curve corresponding to the other charging process, and two peaks corresponding to the two target peak values being used for representing the same electrochemical reaction;
and determining the performance of the power battery according to the relative change rate of internal resistance capacity and a relative change rate of internal resistance capacity range corresponding to fault type.

2. The method of claim 1, wherein the step of determining the performance of the power battery according to the relative change rate of internal resistance capacity and the relative change rate of internal resistance capacity range corresponding to fault type comprises:
judging whether the relative change rate of internal resistance capacity falls within the relative change rate of internal resistance capacity range corresponding to fault type;
if yes, determining that the performance of the power battery is abnormal, and/or determining that the power battery has a fault corresponding to the fault type;
and if no, determining that the performance of the power battery is normal.

3. The method of claim 2, further comprising the steps of:
if the relative change rate of internal resistance capacity falls within the relative change rate of internal resistance capacity range corresponding to fault type, outputting a warning message;
wherein the warning message is configured to represent a performance abnormity of the power battery and/or existence of the fault of the power battery corresponding to fault type.

4. The method of claim 1, wherein the step of calculating the relative change rate of internal resistance capacity in any two charging processes comprises:
determining the target peak value of the first dQ/dV curve and the target peak value of the second dQ/dV curve based on initial charge levels during the two charging processes.

5. A system for determining performance of a power battery, comprising:
a data acquisition module configured to acquire historical data of the power battery in at least two charging processes;
a first determination module configured to determine, according to historical data in one charging process, a dQ/dV curve and a direct current internal resistance corresponding to said charging process;
a change rate calculation module configured to calculate a relative change rate of internal resistance capacity in any two charging processes; wherein the relative change rate of internal resistance capacity is determined according to a difference between a first direct current internal resistance and a second direct current internal resistance and a difference between a target peak value of a first dQ/dV curve and a target peak value of a second dQ/dV curve, the first direct current internal resistance and the first dQ/dV curve corresponding to one charging process, the second direct current internal resistance and the second dQ/dV curve corresponding to the other charging process, and two peaks corresponding to the two target peak values being configured to represent the same electrochemical reaction;
and a second determination module configured to determine the performance of the power battery according to the relative change rate of internal resistance capacity and the relative change rate range of internal resistance capacity range corresponding to fault type.

6. The system of claim 5, wherein the second determination module is configured to determine whether the relative change rate of internal resistance capacity falls within the relative change rate of internal resistance capacity range corresponding to fault type, and if yes, determine that the performance of the power battery is abnormal, and/or determine that the power battery has a fault corresponding to the fault type; and if no, determine that the performance of the power battery is normal.

7. The system of claim 6, further comprising a message notification module configured to output a warning message if the relative change rate of internal resistance capacity falls within the relative change rate of internal resistance capacity range corresponding to fault type;
wherein the warning message is configured to represent a performance abnormity of the power battery and/or existence of the fault of the power battery corresponding to the fault type.

8. The system of claim 5, wherein the change rate calculation module is further configured to determine the target peak value of the first dQ/dV curve and the target peak value of the second dQ/dV curve based on initial charge levels during the two charging processes.

9. An electronic device comprising a memory, a processor, and a computer program stored on the memory and executable on the processor, wherein the processor implements the method for determining the performance of a power battery according to claim 1 when executing the computer program.

10. A computer-readable storage medium on which a computer program is stored, which, when executed by a processor, implements the method for determining the performance of a power battery according to claim 1.
